(19) United States
(12) Patent Application Publication
(10) Pub. No.: US 2015/0282351 A1
(43) Pub. Date: Oct. 1, 2015

(54) HOUSING INCLUDING A SEALED HEADING

(71) Applicant: VALEO SYSTEMES DE CONTROLE MOTEUR, Cergy Saint Christophe (FR)

(72) Inventors: Guillaume Bonvallat, Meru (FR); Damien Lamouche, Crosne (FR); Bruno Couloigner, Mur Et Regnier (FR); Philippe Guillot, Angers (FR)

(73) Assignee: VALEO SYSTEMES DE CONTROLE MOTEUR, Cergy Saint Christophe (FR)

(21) Appl. No.: 14/435,198

(22) PCT Filed: Sep. 26, 2013
(86) PCT No.: PCT/FR2013/052275

§ 371 Date: Apr. 13, 2015

(30) Foreign Application Priority Data
Oct. 23, 2012 (FR) 1260091

(51) Int. Cl. H05K 5/02; H05K 5/03; B29C 65/60

(52) U.S. Cl. CPC H05K 5/0217; B29C 65/606; H05K 5/03; B29L 2031/3481

(57) ABSTRACT

The invention relates to a housing comprising: a chamber; a cover (12); and a means (111) for attaching the chamber to the cover. Said cover comprises a hole (121), said hole (121) being suitable for having the attachment means (111) pass therethrough, one end of the attachment means (111) projecting from the hole (121), such to have the shape thereof changed by means of heading. The invention is characterized in that the cover (12) comprises a continuous reinforcement (122) on the edge of the hole (121), and in that, during heading of the end of the attachment means (111), the reinforcement (122) melts at least partially in contact with the end of the attachment means (111) such as to form a weld.

### TECHNICAL FIELD OF THE INVENTION

The invention relates to a sealed housing. It relates more specifically to a sealed housing containing a printed circuit board for applications in the automobile sector, for example a starter-motor control interface housing. Such housings must be sealed against moisture and/or dust to guarantee the correct operation of the electrical and electronic elements that they contain.

In the context of this application, heading shall mean the partial deformation of a part in order to create a mechanical link between said part and another part.

### PRIOR ART

FIG. 1 shows an existing sealed housing 1. The sealed housing 1 includes attachment tabs 14 used to attach the housing 1 to another element (or to several other elements), such as a wall to which the housing is attached. It includes a chamber 11 in which are arranged the elements to be contained in the housing and protected from moisture and/or dust, for example a printed circuit board. The chamber 11 is intended to be closed by a cover (not shown in FIG. 1). The chamber 11 is closed by the cover by attaching the chamber to the cover using attachment means 111 rigidly connected to the chamber and designed to pass through a hole formed in the cover of the housing 1. The attachment means 111 attach the chamber to the cover by means of one extremity of the attachment means that can be deformed by heading and that projects through the hole formed in the cover of the housing 1.

Sealing means 13, for example a gasket, are placed along the length of the chamber 11 of the housing 1 and form a closed sealed zone 113 (once the chamber has been closed by the cover) in the chamber of the housing 1. The elements, such as printed circuit boards, to be protected against dust and moisture are placed inside the zone 113. Once the cover has been attached to the chamber 13, and the housing has been closed, the zone 113 needs to be kept sealed.

A major drawback of this type of housing is the size of same, and size must always be minimized in the automobile sector. In this case, the attachment means 111 are arranged on the attachment tabs 14, and a space must be reserved for same on these tabs 14. The presence of attachment means 111 on an attachment tab results in a size that is larger than the size resulting from:
the intrinsic dimensions of the housing, i.e. the dimensions of the chamber and of the cover;
plus the dimensions of the tabs 14 for attaching the housing 1 to other elements.

If the housing is being used in a vehicle passenger compartment, space-saving is always sought after and the presence of attachment means 111 on the attachment tabs 14 results in a costly loss of space in the passenger compartment of a vehicle. However, it is not possible to move the attachment means 111 away from the attachment tabs 14 to place them with the gasket 13 or the sealed zone 113, since this would create a sealing problem for the housing. Indeed, such attachment means 111 pass through a hole formed in the cover of the housing, and there may be sealing problems around the hole. This sealing problem is visible in particular with reference to FIGS. 2A and 2B.

FIGS. 2A and 2B show a cover 12 of an existing housing 1, a hole 121 being formed in said cover 12. Attachment means 111, in this case a heading pin, rigidly connected to the chamber (not shown in these figures) of the housing 1 can be seen in FIGS. 2A and 2B.

The attachment means 111 pass through the hole 121, and one extremity 112 of the attachment means 111 projects through the hole 121. This extremity 112 of the attachment means 111 can be deformed by heading. In FIG. 2A, the extremity 112 of the attachment means is tubular, before heading. The chamber is not attached to the cover 12 in FIG. 2A.

After heading, in FIG. 2B, the extremity 112 of the attachment means is deformed (in this case into a rounded shape) and attaches the chamber, the attachment means 111 of which is rigidly connected to the cover 12. Indeed, the deformation caused by the heading of the extremity 112 of the attachment means creates a mechanical link between the attachment means 111 and the cover 12. However, the sealing of the inside of the housing is not guaranteed around the contact zones 2 between the cover and the attachment means 111. Consequently, such attachment means 111 cannot be moved from an attachment tab of the cover to the sealed zone without jeopardizing the seal of the sealed zone.

### DESCRIPTION OF THE INVENTION

The invention is intended to overcome the aforementioned drawbacks in the prior art in full or in part, and in particular to propose means for attaching the cover of a sealed housing to the chamber of a sealed housing in such a way as to guarantee the seal while enabling the size of the housing to be reduced.

In this drawing, one aspect of the invention relates to a sealed housing comprising:
a chamber;
a cover;
means for attaching the chamber to the cover;
   said cover having a hole, said hole being designed such that the attachment means can pass through; one extremity of said attachment means projecting through the hole to be deformed by heading; the cover having a continuous reinforcement around the hole, the reinforcement melting at least partially in contact with the extremity of the attachment means such as to form a weld during heading of the extremity of the attachment means.

During heading of the extremity of the attachment means, in order to deform this part to create a mechanical link between the cover and the attachment means, the extremity of the attachment means is partially melted by the heat generated during heading. The heat generated during heading softens the extremity of the attachment means, as well as the continuous reinforcement around the hole through which the extremity of the attachment means projects. This softening enables the materials forming the reinforcement and the extremity of the attachment means to mix with each other to make a weld between the reinforcement and the extremity of the attachment means. This weld, which is guaranteed between the two elements, ensures the seal around the contact zones between the cover (via the reinforcement) and the attachment means. Such sealed attachment means can therefore be used on any point of the housing without jeopardizing the seal of the housing, and can in particular be used within a sealed zone of the housing in order to reduce the size of the housing.

In addition to the main features set out in the above paragraph, the housing according to the invention may have one or more of the following complementary features, taken individually or in any technically possible combination:
the height of the reinforcement is at least equal to the height of the extremity of the attachment means after heading. The height of the extremity of the attachment means after heading shall mean the maximum height of the extremity of the attachment means after heading. Indeed, after heading, the height of the extremity of the attachment means is not necessarily uniform;
the chamber includes sealing means, said sealing means being designed to define a closed, sealed zone of the chamber. The sealed zone is for example defined when the cover of the housing is positioned on the chamber of the housing;
the attachment means are placed inside said closed, sealed zone of the chamber. Placing the attachment means inside the sealed zone, and not outside the sealed zone, advantageously limits the size of the sealed housing to the size of the elements that the sealed housing is intended to contain, without jeopardizing the seal of the housing;
the attachment means are a heading pin;
said attachment means are rigidly connected to said chamber;
the attachment means are a pin extending from the surface of the chamber;
the reinforcement is a collar, said collar being integral with the cover; and
the chamber is designed to receive a printed circuit board.

The invention also relates to a method for making a housing according to one of the embodiments described above, including:
a step in which the attachment means are inserted into the hole;
a step in which the extremity of the attachment means projecting through the hole is headed; said heading step involving a release of heat causing the reinforcement in contact with the extremity of the attachment means to melt at least partially, thereby forming a weld.

The invention also relates to a method for joining two parts together, characterized in that it includes:
the provision of a first element comprising attachment means;
the provision of a second element comprising a hole and a continuous reinforcement around the hole;
a step in which the attachment means are inserted into the hole, one extremity of said attachment means projecting through the hole;
a step in which said extremity of the attachment means is headed; said heading step involving a release of heat causing the reinforcement in contact with the extremity of the attachment means to melt at least partially, thereby forming a weld.

The first element may include any one of the features of the chamber described above. The second element may include any one of the features of the cover described above.

In addition to the main features mentioned in the above paragraphs, the methods according to the invention may have the following complementary feature:
the heading step is a hot-heading step.

### SHORT DESCRIPTION OF THE FIGURES

Other features and advantages of the invention are set out in the description below, with reference to the attached figures, which show:

FIG. 1, a schematic view of a housing according to the prior art;

FIG. 2A, a schematic view of means for attaching a chamber to a cover of a housing according to the prior art, before heading of an extremity of the attachment means;

FIG. 2B, a schematic view of the attachment means in FIG. 2A after heading of the extremity of the attachment means;

FIG. 3A, a schematic view of means for attaching a chamber to a cover of a housing according to one embodiment of the invention, before heading of an extremity of the attachment means;

FIG. 3B, a schematic view of the attachment means in FIG. 3A after heading of the extremity of the attachment means; and

FIG. 4, a schematic view of a housing according to an embodiment of the invention.

For the sake of clarity, identical or similar elements are indicated using the same reference signs in all of the figures.

### DETAILED DESCRIPTION OF AN EMBODIMENT

A cover 12 of a sealed housing including a hole 121 is shown in FIGS. 3A and 3B. The cover 12 has a continuous reinforcement 122 around the hole 121. Continuous reinforcement around the hole means a reinforcement surrounding the hole with no gaps. Such a reinforcement 122 may be made of plastic. This reinforcement 122 may be a collar that is integral with the cover 12. For example, the collar may be molded directly in the material of the cover when the cover 12 is manufactured.

FIGS. 3A and 3B also show attachment means 111 of the chamber of the housing (the chamber is not shown in these figures). In this example embodiment, the attachment means 111 are a heading pin.

The heading pin is inserted into the hole 121 to enable the cover 12 to be attached to the chamber after the pin has been headed. The chamber (not shown in these figures) is rigidly connected to the attachment means, for example by molding the attachment means on the chamber.

One extremity 112 of the heading pin 111 projects through the hole 121. This extremity 112 may for example be made of plastic. The attachment means 111 may be made entirely of the same material as the extremity 112 of the attachment means, such as to facilitate molding of the elements.

FIG. 3A shows the extremity 112 before heading, and FIG. 3B shows the same extremity 112 after heading. When heading the extremity 112 of the attachment means, in order to deform said extremity 112 of the attachment means, heat is released near to the extremity 112 to allow the plastic to be deformed. The rounded shape of the extremity 112 of the heading pin shown in FIG. 3B after heading is a non-limiting example.

Once the extremity of the attachment means, in this example made of plastic, is deformable (i.e. once enough heat has been released to reach a temperature close to the melting temperature of the plastic), a mold is placed above the extremity 112 of the attachment means. The mold is used to correctly shape the headed part, in this case the extremity 112 of the heading pin. The rounded shape, for example given to the extremity 112 of the attachment means shown in FIG. 3B, provides a mechanical link between the chamber and the cover 12. The heading may for example be hot heading (deformation of the plastic using a part releasing heat, i.e. thermode) or cold heading (deformation of the plastic after the plastic has been heated by the vibrations of a sonotrode, the sonotrode not releasing any heat directly.

The heat released during heading near to the extremity 112 of the attachment means also at least partially melts the reinforcement 122, which is made of plastic in this example embodiment. This fusion of the plastic of the reinforcement 122 in contact with a portion of the extremity 112 of the attachment means enables the constituent material of same to mix together, thereby creating a weld 123. The weld 123 thus formed around the contact interface between the reinforcement and the extremity of the attachment means provides the seal around the hole 121. The weld 123 also provides a mechanical reinforcement of the mechanical link formed by the heading of the extremity 112 of the attachment means. Among other things, this mechanical reinforcement improves the impact strength, holding strength and shear strength of the mechanical link.

The materials forming the extremity 112 of the attachment means and the reinforcement 122 may be different or the same.

The height Ha of the extremity 112 of the attachment means after heading (shown in FIG. 3B) is less than the height before heading (not referenced in FIG. 3A). This variation in height is due to the fusion of the plastic forming the extremity 112 of the attachment means and to the deformation of same by heading. In order to ensure an optimal sealing around the contact zones 2 between the cover (via the reinforcement 122) and the attachment means 111, the height Hr of the reinforcement 122 is at least equal to the height Ha of the extremity 112 of the attachment means after heading. This height Ha of the extremity 112 of the attachment means after heading is the maximum height of said extremity 112. In the example shown in FIG. 3B, this is the height around the center of the extremity 112 after heading.

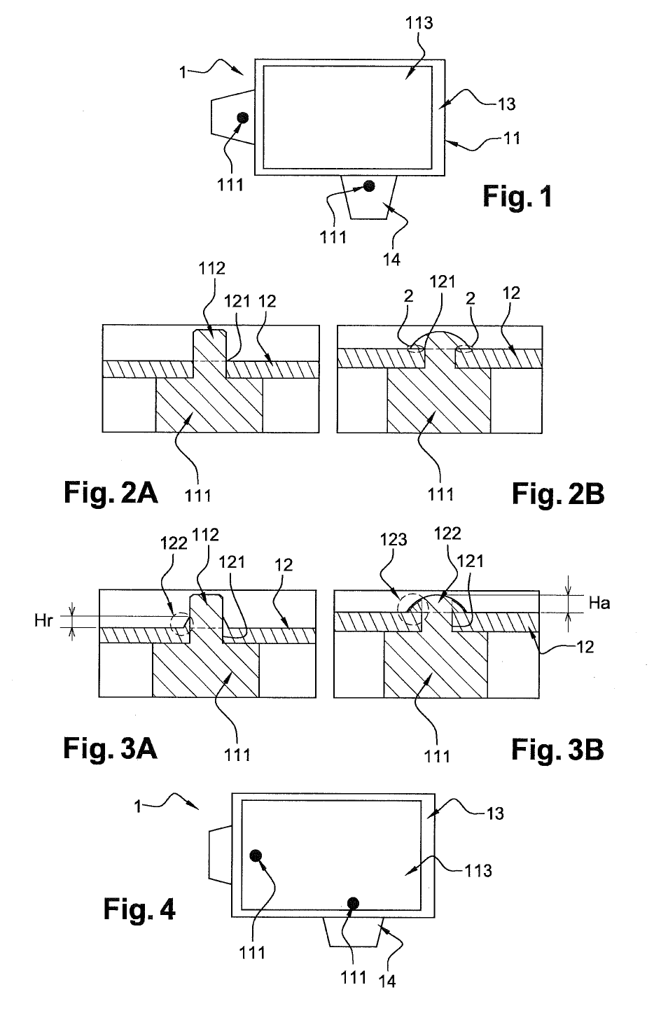

Once the attachment means between the chamber and the cover have been sealed, these attachment means 111 can be placed within the sealed zone of the housing 1, as shown in FIG. 4. Comparison between FIGS. 1 and 4 shows that the tabs 14 used to attach the housing 1 to another element are smaller. Indeed, the attachment means 111 between the chamber and the cover of the housing may be moved towards the inside of the housing 1 within the sealed zone 113 without jeopardizing the seal required for the correct operation of the elements contained in this sealed zone, for example a printed circuit board.

The invention is not limited to the embodiments described above with reference to the figures, and variants may be considered without thereby moving outside the scope of the invention.

1. A housing comprising:
a chamber;
a cover;
means for attaching the chamber to the cover;
said cover having a hole, wherein the attachment means passes through the hole,
one extremity of said attachment means projecting through the hole to be deformed by heading,
wherein the cover has a continuous reinforcement around the hole and the reinforcement melts at least partially in contact with the extremity of the attachment means to form a weld during heading of the extremity of the attachment means.

2. The housing as claimed in claim 1, wherein the height of the reinforcement is at least equal to the height of the extremity of the attachment means after heading.

3. The housing as claimed in claim 1, wherein the chamber includes sealing means, said sealing means being designed to define a closed, sealed zone of the chamber.

4. The housing as claimed in claim 3, wherein the attachment means are placed inside said closed, sealed zone of the chamber.

5. The housing as claimed in claim 1, wherein the attachment means are a heading pin.

6. The housing as claimed in claim 1, wherein the reinforcement is a collar, said collar being integral with the cover.

7. The housing as claimed in claim 1, wherein the chamber is configured to receive a printed circuit board.

8. A method for making a housing as claimed in claim 1, the method comprising:
a step in which the attachment means are inserted into the hole;
a step in which the extremity of the attachment means projecting through the hole is headed, said heading step involving a release of heat causing the reinforcement in contact with the extremity of the attachment means to melt at least partially, thereby forming a weld.

9. The method as claimed in claim 8, wherein the heading step is a hot-heading step.

10. A method for joining two parts, comprising:
the provision of a first element comprising attachment means;
the provision of a second element comprising a hole and a continuous reinforcement around the hole;
a step in which the attachment means are inserted into the hole, one extremity of said attachment means projecting through the hole; and
a step in which said extremity of the attachment means is headed, said heading step involving a release of heat causing the reinforcement in contact with the extremity of the attachment means to melt at least partially, thereby forming a weld.
